(19) United States
(12) Patent Application Publication
(10) Pub. No.: US 2020/0194596 A1
(43) Pub. Date: Jun. 18, 2020

(54) THIN FILM TRANSISTOR COMPRISING TWO DIMENSIONAL MATERIAL, DISPLAY COMPRISING THE SAME AND MANUFACTURING METHOD FOR THE SAME

(71) Applicant: KOREA ADVANCED INSTITUTE OF SCIENCE AND TECHNOLOGY, Daejeon (KR)

(72) Inventors: Sung-Yool CHOI, Daejeon (KR); Taegyu KANG, Daejeon (KR); Sung Gap IM, Daejeon (KR)

(73) Assignee: KOREA ADVANCED INSTITUTE OF SCIENCE AND TECHNOLOGY, Daejeon (KR)

(21) Appl. No.: 16/226,897

(22) Filed: Dec. 20, 2018

(30) Foreign Application Priority Data
Dec. 14, 2018 (KR) 10-2018-0162127

(51) Int. Cl. H01L 29/786; H01L 29/51; H01L 29/66

(52) U.S. Cl. CPC H01L 29/78684; H01L 29/66969; H01L 29/517; H01L 29/511

(57) ABSTRACT

Provided is a thin-film transistor containing source, drain and gate electrodes, which contains: a channel layer containing a two-dimensional material; a gate insulator formed on the channel layer; and a gate electrode formed on the gate insulator, wherein the gate insulator contains at least two insulators having different dielectric constants.

### TECHNICAL FIELD

The present disclosure relates to a thin-film transistor containing a two-dimensional material, a display containing the same and a method for manufacturing the same, more particularly to a thin-film transistor containing a two-dimensional material, which can be used as a switching device for a high-resolution display, etc. by solving the problem that the effect of reducing scattering is not significant because of increased surface phonon scattering due to the surface characteristics of a high-k insulator, a display containing the same and a method for manufacturing the same.

### BACKGROUND ART

As typical two-dimensional materials, transition metal dichalcogenide compounds (TMDCs) are being studied a lot as next-generation display channel materials due to high mobility, atomic-layer-scale small thickness and high flexibility, transparency, etc. resulting from the thickness.

However, transistors using the transition metal dichalcogenide compounds exhibit low mobility characteristics due to various factors.

A typical factor affecting high mobility is scattering. Two-dimensional semiconductors are largely affected by charged impurity scattering and electron-phonon scattering.

In most researches, high-k insulators are used to reduce the charged impurity scattering or substrates are changed to reduce the electron-phonon scattering. However, satisfactory TMDC-based transistors are not available yet.

### DISCLOSURE

### Technical Problem

The present disclosure is directed to providing a transistor based on a two-dimensional material thin film and a method for manufacturing the same.

### Technical Solution

The present disclosure provides a thin-film transistor containing source, drain and gate electrodes, which contains: a channel layer containing a two-dimensional material; a gate insulator formed on the channel layer; and a gate electrode formed on the gate insulator, wherein the gate insulator contains at least two insulators having different dielectric constants.

In an exemplary embodiment of the present disclosure, a first insulator and a second insulator are provided between the channel layer and the gate electrode and the first insulator adjacent to the channel layer has a higher dielectric constant than the second insulator adjacent to the gate electrode.

In an exemplary embodiment of the present disclosure, the channel layer is a transition metal dichalcogenide compound (TMDC) thin film.

In an exemplary embodiment of the present disclosure, the second insulator is a pV3D3 (poly(1,3,5-trimethyl-1,3,5-trivinylcyclotrisiloxane)) polymer and the first insulator is a metal oxide.

In an exemplary embodiment of the present disclosure, a ratio (k₁/k₂) of the dielectric constant (k₁) of the first insulator and the dielectric constant (k₂) of the second insulator is 2 or greater.

The present disclosure also provides a display containing the thin-film transistor described above as a switching device.

The present disclosure also provides a method for manufacturing a thin-film transistor, including: a step of forming a gate electrode on a substrate; a step of forming a first insulator on the gate electrode; a step of forming a second insulator on the first insulator; and a step of transferring a channel thin film containing a transition metal dichalcogenide compound onto the second insulator, wherein the first insulator has a higher dielectric constant than the second insulator.

In an exemplary embodiment of the present disclosure, the second insulator is a pV3D3 (poly(1,3,5-trimethyl-1,3,5-trivinylcyclotrisiloxane)) polymer and the first insulator is a metal oxide.

In an exemplary embodiment of the present disclosure, the method for manufacturing a thin-film transistor further includes, after the step of transferring the channel thin film containing the transition metal dichalcogenide compound onto the second insulator, a step of forming source and drain electrodes on the substrate.

### Advantageous Effects

A transistor device according to the present disclosure can solve the problem that the effect of reducing scattering is not significant because of increased surface phonon scattering due to the surface characteristics of a high-k insulator. Therefore, the phonon scattering effect of the existing two-dimensional transistor can be reduced and a high-performance transistor having a two-dimensional structure can be provided.

### BRIEF DESCRIPTION OF DRAWINGS

The patent or application file contains a least one drawing executed in color. Copies of this patent or patent application publication with color drawing(s) will be provided by the Office upon request and payment of the necessary fee

FIG. 1 is a schematic view of a TMDC-based thin-film transistor according to an exemplary embodiment of the present disclosure.

FIG. 2 is an image of a transistor device prepared according to an exemplary embodiment of the present disclosure.

FIGS. 3A-3B shows an operation characteristics test result of a transistor device using a multilayer gate stack (Al₂O₃/pV3D3) according to the present disclosure.

FIGS. 4A-4D shows a test result of comparing device characteristics depending on insulators.

FIGS. 5A-5B shows a test result showing the temperature dependence of a device.

FIGS. 6A-6B shows flicker noise characteristics data and a comparative test result of a device according to the present disclosure.

FIGS. 7A-7D shows a flexibility test result of a device manufactured according to the present disclosure.

FIG. 8 is a flow diagram of a method for manufacturing a transistor device according to an exemplary embodiment of the present disclosure.

### BEST MODE

Hereinafter, the present disclosure is described in more detail through drawings and examples.

The present disclosure provides a flexible thin-film transistor having a molybdenum disulfide channel with high mobility using a multilayer gate stack (high-k oxide film/low-k polymer).

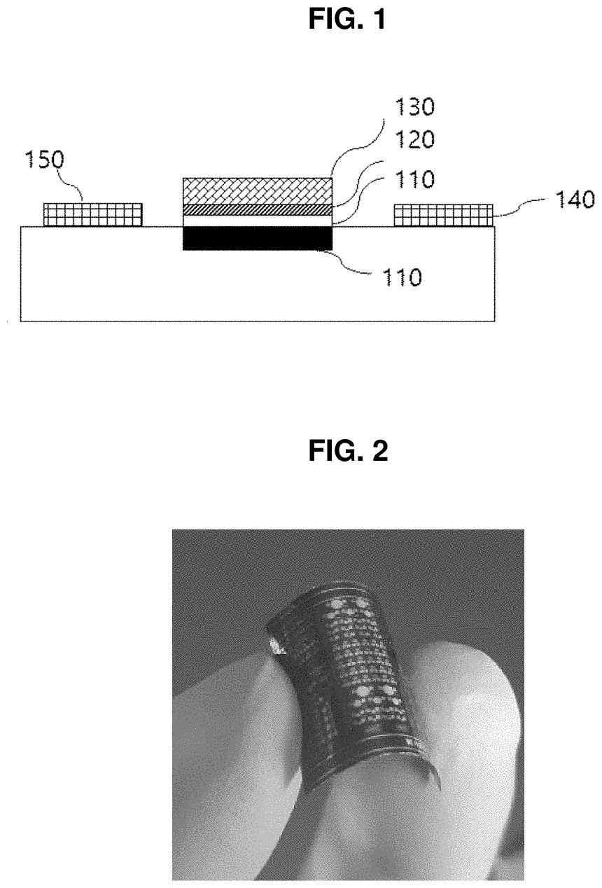

FIG. 1 is a schematic view of a TMDC-based thin-film transistor according to an exemplary embodiment of the present disclosure.

Referring to FIG. 1, the TMDC-based thin-film transistor according to the present disclosure contains a TMDC thin film channel 110, source and drain electrodes 140, 150 and a gate electrode 130. In addition, the TMDC thin-film transistor according to the present disclosure contains a multilayer insulator which is provided between the TMDC thin film channel and the gate electrode and contains a first insulator 120 having a high dielectric constant (high k) and a second insulator 130 having a low dielectric constant (low k).

The transistor according to the present disclosure has a structure wherein a low-k polymer having a low dielectric constant is interposed between a high-k insulator and a two-dimensional semiconductor. This can solve the problem of the existing method of reducing scattering by impurities using an insulator having a high dielectric constant, i.e., the problem that the effect of reducing scattering is not significant because of increased surface phonon scattering due to the surface characteristics of the high-k insulator. Therefore, according to the present disclosure, the phonon scattering effect of the existing two-dimensional transistor can be reduced and a high-performance transistor having a two-dimensional structure can be provided.

In an exemplary embodiment of the present disclosure, Al₂O₃ as the first insulator has a dielectric constant k₁ of 6 and pV3D3 as the second insulator has a dielectric constant k₂ of 2.2. In this case, the ratio of the dielectric constants (k₁/k₂) at the gate insulator is about 2.7. If the insulator is HfO (k₁=20), the dielectric constant is about 10. Therefore, it is preferred that the ratio of the high dielectric constant and the low dielectric constant (k₁/k₂) is 2 or greater. If the ratio is smaller, the effect of reducing surface phonon scattering is insignificant.

Hereinafter, the present disclosure is described in more detail through an example and a test example.

### Example

In order to mitigate the surface roughness of a commercially available polymer film, an epoxy resin-based SU-8 solution was coated and then cured by treating with UV. Then, three metal layers of Cr/Au/Pd were deposited sequentially for use as a gate electrode.

The electrode deposition may be conducted by any common method. Photolithography, thermal evaporation, lift-off, etc. may be employed and all these processes belong to the scope of the present disclosure.

Then, an Al₂O₃ film to be used as an insulator was deposited by ALD (atomic layer deposition). Additionally, a pV3D3 (poly(1,3,5-trimethyl-1,3,5-trivinylcyclotrisiloxane)) polymer was deposited by iCVD (initiated chemical vapor deposition) for deposition of a multilayer gate stack.

The second insulator pV3D3 had a thickness of about 15 nm. If the thickness is larger, carrier density is decreased a lot due to decreased gate capacitance. In this case, mobility may be improved but the actual current may be decreased.

Then, a molybdenum disulfide thin film formed by CVD was transferred onto the formed gate electrode. For the transfer, wet transfer was conducted using polystyrene as a support layer.

Then, a channel region was patterned through photolithography and O₂ plasma etching and Ti/Au metals were deposited as source/drain electrodes in the same manner as for the gate electrode. Finally, Al₂O₃ was deposited by ALD.

FIG. 2 is an image of the transistor device manufactured according to the present disclosure.

Referring to FIG. 2, it can be seen that a thin-film transistor device with sufficiently flexible property can be manufactured.

### Test Example

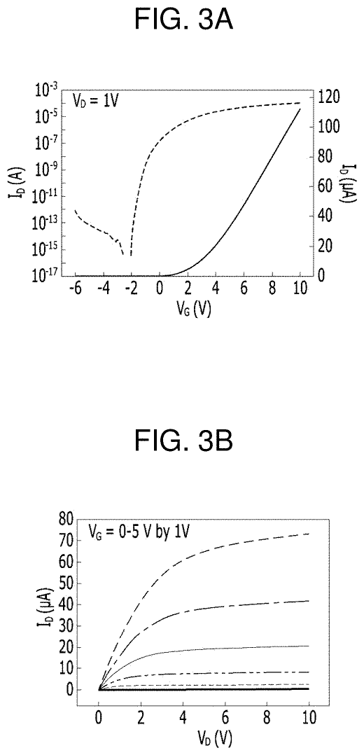

FIGS. 3A and 3B show an operation characteristics test result of the transistor device using the multilayer gate stack (Al₂O₃/pV3D3) according to the present disclosure.

Referring to FIGS. 3A and 3B, the transistor according to the present disclosure device exhibits current and output characteristics applicable to displays such as an organic light-emitting diode (OLED).

FIG. 3A shows the transfer characteristics of the transistor and FIG. 3B shows the output characteristics of the transistor. In particular, it can be seen that transistor device according to the present disclosure exhibits stable response characteristics as evidenced by the current saturation as shown in FIG. 3B.

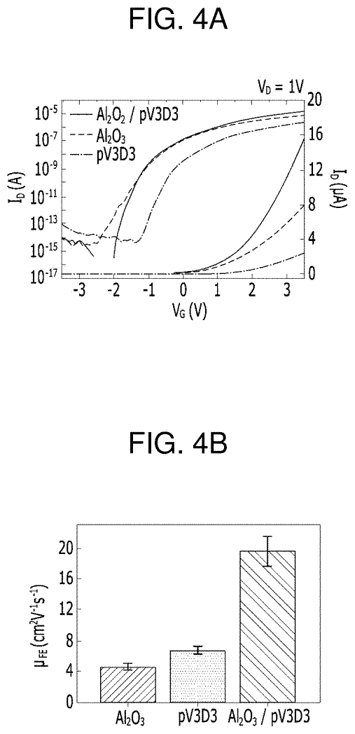

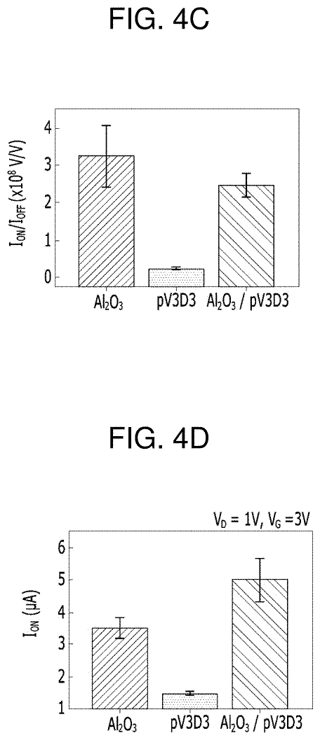

FIGS. 4A-4D shows a test result of comparing device characteristics depending on insulators.

Referring to FIGS. 4A-4D, it can be seen that the insulator according to the present disclosure (Al₂O₃/pV3D3) exhibits remarkably superior characteristics as compared to the high-k insulator (Al₂O₃, k₁=6) or the low-k insulator (pV3D3, k₂=2.2). In particular, it exhibits remarkably superior mobility as compared to the single thin films.

The insulator having a multilayer stack structure according to the present disclosure exhibits such high mobility because the high-k inorganic insulator which ensures the stability of the insulator and reduces the effect of charged impurity scattering and the low-k insulator which reduces the effect of optical-phonon scattering on the surface are used together.

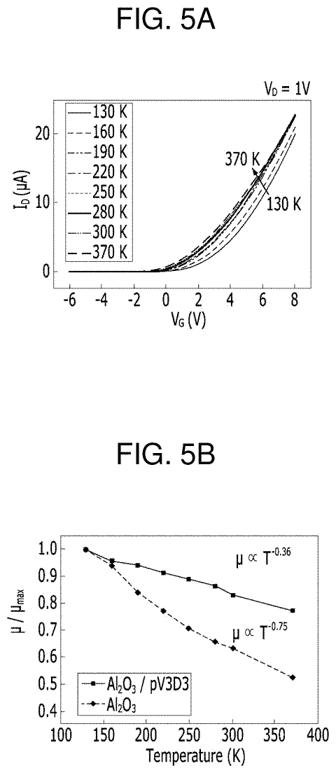

FIGS. 5A-5B shows a test result showing the temperature dependence of the device.

The relative intensity of phonon scattering was compared depending on temperature. It was confirmed that the device using the multilayer gate stack exhibits lower temperature dependence as compared to the device using the high-k insulator only (see FIG. 5B. This suggests that the effect of phonon scattering was reduced.

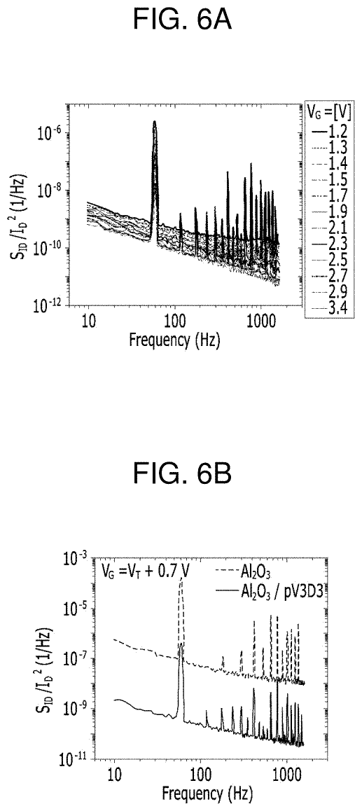

FIGS. 6A-6B show flicker noise characteristics data and a comparative test result of the device according to the present disclosure.

Referring to FIG. 6A, the device manufactured according to the present disclosure showed 1/f flicker noise characteristics.

Also, referring to FIG. 6B, it can be seen that the device using the multilayer gate stack exhibits remarkably lower noise spectral density as compared to the device using a single insulator. This suggests that the scattering of the channel and the insulator was reduced and the presence of less trap sites on the polymer surface as compared to the high-k insulator improved noise characteristics.

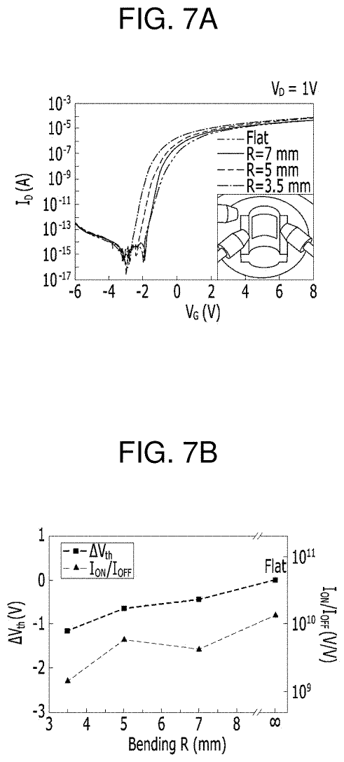

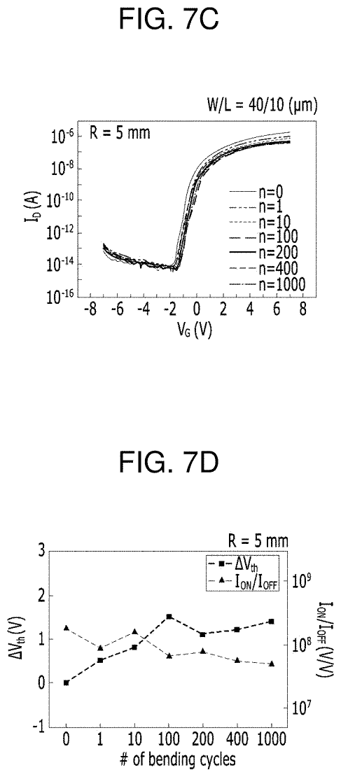

FIGS. 7A-7D shows a flexibility test result of the device manufactured according to the present disclosure.

Referring to FIGS. 7A-7D, it can be seen that the change in operation characteristics is not large even for high radius of curvature.

As described above, the present disclosure solves the problem that the effect of reducing scattering is not significant because of increased surface phonon scattering due to the surface characteristics of the high-k insulator by interposing the low-k insulator between the TMDC two-dimensional channel thin film such as MoS₂.

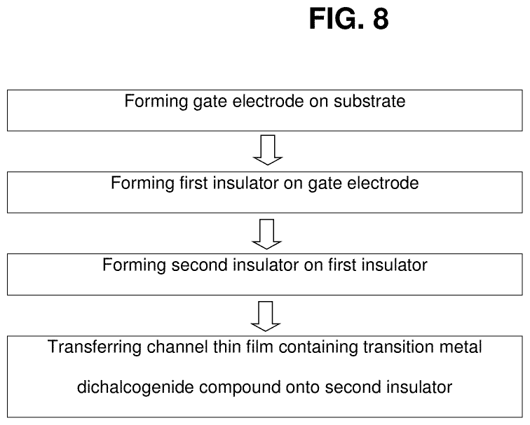

FIG. 8 is a flow diagram of a method for manufacturing a transistor device according to the present disclosure.

Referring to FIG. 8, the method according to the present disclosure includes: a step of forming a gate electrode on a substrate; a step of forming a first insulator on the gate electrode; a step of forming a second insulator on the first insulator; and a step of transferring a channel thin film containing a transition metal dichalcogenide compound onto the second insulator, wherein the first insulator has a higher dielectric constant than the second insulator.

The order of the steps may be changed. For example, after the channel thin film is transferred, the insulators may be formed in sequence and then the gate electrode may be formed.

In an exemplary embodiment of the present disclosure, the second insulator is pV3D3 (poly(1,3,5-trimethyl-1,3,5-trivinylcyclotrisiloxane)) polymer and the first insulator is a metal oxide.

The present disclosure solves the scattering problem of the existing two-dimensional thin film transistor by interposing an insulator having a low dielectric constant and is also advantageous in that the process is relatively simple and easy.

1. A thin-film transistor comprising source, drain and gate electrodes, which comprises:
a channel layer comprising a two-dimensional material;
a gate insulator formed on the channel layer; and
a gate electrode formed on the gate insulator,
wherein the gate insulator comprises at least two insulators having different dielectric constants.

2. The thin-film transistor according to claim 1, wherein a first insulator and a second insulator are provided between the channel layer and the gate electrode and the first insulator adjacent to the channel layer has a higher dielectric constant than the second insulator adjacent to the gate electrode.

3. The thin-film transistor according to claim 1, wherein the channel layer is a transition metal dichalcogenide compound (TMDC) thin film.

4. The thin-film transistor according to claim 2, wherein the second insulator is a pV3D3 (poly(1,3,5-trimethyl-1,3,5-trivinylcyclotrisiloxane)) polymer and the first insulator is a metal oxide.

5. The thin-film transistor according to claim 1, wherein a ratio (k₁/k₂) of the dielectric constant (k₁) of the first insulator and the dielectric constant (k₂) of the second insulator is 2 or greater.

6. A display comprising the thin-film transistor according to claim 1 as a switching device.

7. A method for manufacturing a thin-film transistor, comprising:
a step of forming a gate electrode on a substrate;
a step of forming a first insulator on the gate electrode;
a step of forming a second insulator on the first insulator; and
a step of transferring a channel thin film comprising a transition metal dichalcogenide compound onto the second insulator,
wherein the first insulator has a higher dielectric constant than the second insulator.

8. The method for manufacturing a thin-film transistor according to claim 7, wherein the second insulator is a pV3D3 (poly(1,3,5-trimethyl-1,3,5-trivinylcyclotrisiloxane)) polymer and the first insulator is a metal oxide.

9. The method for manufacturing a thin-film transistor according to claim 7, which further comprises, after the step of transferring the channel thin film comprising the transition metal dichalcogenide compound onto the second insulator, a step of forming source and drain electrodes on the substrate.
